(19) United States
(12) Patent Application Publication
(10) Pub. No.: US 2009/0104761 A1
(43) Pub. Date: Apr. 23, 2009

(54) Plasma Doping System With Charge Control

(75) Inventors: Yongbae Jeon, Lexington, MA (US); Vikram Singh, North Andover, MA (US); Timothy Miller, Ipswich, MA (US); Ziwei Fang, Beverly, MA (US); Steven Walther, Andover, MA (US); Atul Gupta, Beverly, MA (US)

Correspondence Address: RAUSCHENBACH PATENT LAW GROUP, LLC, P.O. BOX 387, BEDFORD, MA, 01730, US

(73) Assignee: VARIAN SEMICONDUCTOR EQUIPMENT ASSOCIATES, INC., Gloucester, MA (US)

(21) Appl. No.: 11/875,062

(22) Filed: Oct. 19, 2007

(51) Int. Cl. H01L 21/26; C23C 16/513

(52) U.S. Cl. 438/513; 118/708; 257/E21.311

(57) ABSTRACT

A method of plasma doping includes generating a plasma comprising dopant ions proximate to a platen supporting a substrate in a plasma chamber. The platen is biased with a bias voltage waveform having a negative potential that attracts ions in the plasma to the substrate for plasma doping. At least one sensor measuring data related to charging conditions favorable for forming an electrical discharge is monitored. At least one plasma process parameter is modified in response to the measured data, thereby reducing a probability of forming an electrical discharge.

The section headings used herein are for organizational purposes only and should not to be construed as limiting the subject matter described in the present application.

### BACKGROUND OF THE INVENTION

Plasma processing has been widely used in the semiconductor and other industries for many decades. Plasma processing is used for tasks such as cleaning, etching, milling, and deposition. More recently, plasma processing has been used for doping. Plasma doping is sometimes referred to as PLAD or plasma immersion ion implantation (PIII). Plasma doping systems have been developed to meet the doping requirements of state-of-the-art electronic and optical devices.

Plasma doping systems are fundamentally different from conventional beam-line ion implantation systems that accelerate ions with an electric field and then filter the ions according to their mass-to-charge ratio to select the desired ions for implantation. In contrast, plasma doping systems immerse the target in a plasma containing dopant ions and bias the target with a series of negative voltage pulses. The term “target” is defined herein as the workpiece being implanted, such as a substrate or wafer being ion implanted. The negative bias on the target repels electrons from the target surface, thereby creating a sheath of positive ions. The electric field within the plasma sheath accelerates ions toward the target, thereby implanting the ions into the target surface.

Conventional beam-line ion implantation systems that are widely used in the semiconductor industry have excellent process control and also excellent run-to-run uniformity. Conventional beam-line ion implantation systems provide highly uniform doping across the entire surface of large state-of-the art semiconductor substrates. In addition conventional beam-line ion implantation systems can implant at relatively high doses. Plasma doping systems for the semiconductor industry must also have a very high degree of process control and must be capable of performing ion implants at relatively high doses. However, in general, the process control of plasma doping systems is not as tight as conventional beam-line ion implantation systems. Also, plasma doping systems generally provide implants with a lower range of possible doses and a lower throughput.

### BRIEF DESCRIPTION OF THE DRAWINGS

The invention, in accordance with preferred and exemplary embodiments, together with further advantages thereof, is more particularly described in the following detailed description, taken in conjunction with the accompanying drawings. The drawings are not necessarily to scale, emphasis instead generally being placed upon illustrating principles of the invention.

FIG. 1 illustrates a schematic diagram of a plasma doping system that includes a closed loop charge control system according to the present invention that increases the plasma doping throughput by reducing the probability of forming an electrical discharge.

FIG. 2 illustrates a block diagram of a plasma doping system with closed loop charge control according to the present invention.

FIG. 3 illustrates a flow chart of a method of closed loop charge control of a plasma doping system with various sensors that measure data related to conditions favorable for forming an electrical discharge.

FIG. 4 illustrates a flow chart of a method of closed loop charge control of a plasma doping system that adjusts the duty cycle of the bias voltage waveform so that conditions favorable for forming an electrical discharge are not established.

### DETAILED DESCRIPTION

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

It should be understood that the individual steps of the methods of the present invention may be performed in any order and/or simultaneously as long as the invention remains operable. Furthermore, it should be understood that the apparatus and methods of the present invention can include any number or all of the described embodiments as long as the invention remains operable.

The present teachings will now be described in more detail with reference to exemplary embodiments thereof as shown in the accompanying drawings. While the present teachings are described in conjunction with various embodiments and examples, it is not intended that the present teachings be limited to such embodiments. On the contrary, the present teachings encompass various alternatives, modifications and equivalents, as will be appreciated by those of skill in the art. Those of ordinary skill in the art having access to the teachings herein will recognize additional implementations, modifications, and embodiments, as well as other fields of use, which are within the scope of the present disclosure as described herein. For example, although the present invention is described in connection with a plasma doping system, the methods and apparatus for closed loop charge control applies to many other types of plasma processing systems.

The throughput of a plasma doping system is an important performance metric. The term “throughput” as used herein is defined as the dose provided to the substrate per unit time. The throughput is one important factor in determining the number of wafers per hour that can be processed with a plasma doping system. The value of a plasma doping system is often measured by the system throughput.

Throughput of a plasma doping system can be increases by increasing the dose per bias voltage pulse. The dose per bias voltage pulse can generally be increased by increasing the pulse width and/or frequency of the DC bias voltage pulses applied to the substrate. However, as the pulse width and/or frequency of the DC bias voltage pulses applied to the substrate is increased, the probability of generating an electrical discharge increased. The term “electrical discharge” is defined herein as an electric current, which is rapidly established, that flows when an excess of electric charge finds a discharge path to a surface at a different electrical potential. Electrical discharges are sometimes referred to as electrical arcs or arcs.

Local electrical discharges occur in plasma doping systems when the local electrical potential difference becomes larger than the sheath breakdown voltage of the plasma at the particular local pressure conditions. There are numerous types of possible local electrical discharge mechanisms.

One type of local electrical discharge mechanism is caused by photoresist or other materials on the substrate being ion implanted. Thick photoresist layers, which are commonly used to mask areas on the substrates from exposure to ions, are typically high resistance layer that can accumulate a significant amount of charge. The charge accumulated on these photoresist layers is proportional to the dose per pulse. The accumulated charge forms an electric field at the edges of the substrates that can be sufficient to create an electrical discharge to a surface of the substrate or to a surface in the plasma doping system, such as the shield ring, which is commonly used in plasma doping systems. When an electrical discharge is formed from the accumulated charge on the photoresist to a surface of the substrate, a burst of gas and secondary electrons are generated, which can result in a breakdown of the plasma sheath. The electrical discharge mechanism resulting from charge accumulation typically occurs after the plasma is established, but before or soon after plasma doping is initiated.

Another type of local electrical discharge mechanism is caused by water, solvents, and other volatile chemicals present in the photoresist or other masking layer and other materials present on the substrate which outgas in the process chamber. Significant outgassing will increase the pressure in localized areas with high concentrations of outgassed molecules and, therefore, will increase the probability of breaking down the plasma sheath in these localized areas. The electrical discharge mechanism resulting from molecules outgassed from photoresist and other layers on the substrate tends to occur soon after initiating plasma doping because this type of outgassing rapidly increases when plasma doping is initiated.

The duty cycle of the bias voltage waveform can be specifically chosen to be low enough when plasma doping is initiated to prevent local electrical discharges resulting from outgassing of photoresist and other layers on the substrate. The duty cycle of the bias voltage waveform can then be increases as the concentration of outgassed molecules decreases. For example, the duty cycle can be increased by increasing the pulse width as the concentration of outgassed molecules decreases.

During plasma doping, however, the probability of forming an electrical discharge tends to decrease because the photoresist or other masking layer on the surface of the substrate is doped by the ions impacting the masking layer. In addition, the photoresist or other masking layer carbonizes when exposed to the plasma doping flux, especially at high plasma doping doses. The doping and carbonization increases the electrical conductivity of the photoresist or other masking layer. The increased electrical conductivity enhances the charge dissipation, especially at the edges of the substrate. The enhanced charge dissipation allows a higher dose per pulse to be implanted into the substrate.

It is highly undesirable for a plasma doping system to generate electrical discharges or arcs. Many semiconductor devices are particularly sensitive to high voltage electrical discharges and are easily damaged or destroyed if an electrical discharge or an arc strikes the substrate. Furthermore, electrical discharges that do not strike the substrate are also undesirable because such discharges can change the dose of ions impacting some areas of the substrate, thereby resulting in non-uniformities in the doping across the substrate.

The present invention relates to methods and apparatus for reducing the probability of forming electrical discharges during plasma doping. In particular, the plasma doping apparatus of the present invention includes a closed-loop feedback control system with various sensors that measure data related to conditions favorable for forming an electrical discharge. The closed-loop feedback control system determines certain parameters of the bias voltage waveform and other process parameters that reduce the probability of forming an electrical discharge, thereby allowing the user to increase the dose per pulse, which increases the plasma doping throughput. In one aspect of the invention, electrodes are used that change the charge distribution in the plasma doping apparatus to reduce the probability of forming an electrical discharge. In another aspect of the present invention, a dilution gas is added to the process gas to reduce the electronegativity of plasma.

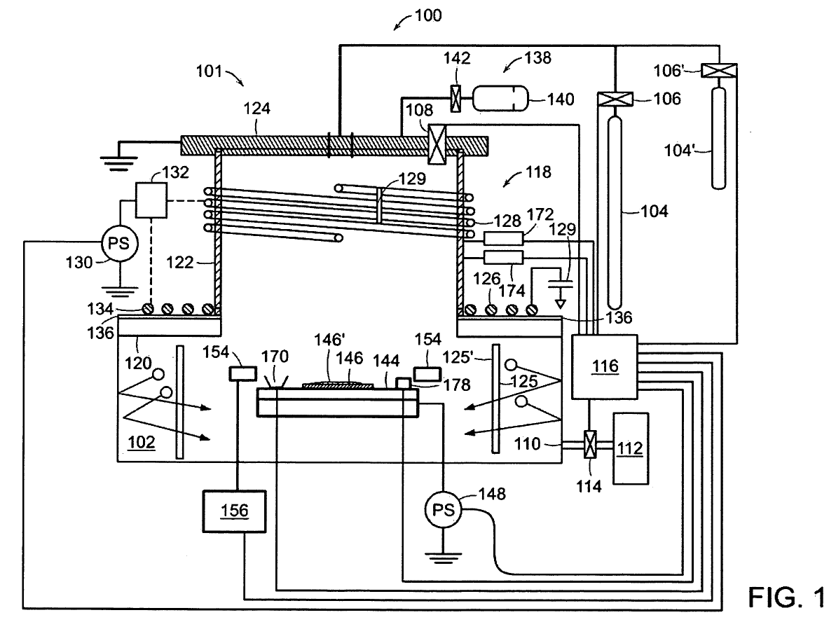

FIG. 1 illustrates a schematic diagram of a plasma doping system 100 that includes a closed loop charge control system according to the present invention that increases the plasma doping throughput by reducing the probability of forming an electrical discharge. A similar plasma doping system is described in U.S. patent application Ser. No. 10/905,172, filed on Dec. 20, 2004, entitled “RF Plasma Source with Conductive Top Section,” which is assigned to the present assignee. The entire specification of U.S. patent application Ser. No. 10/905,172 is incorporated herein by reference. The plasma source 101 shown in the plasma doping system 100 is well suited for plasma doping applications because it can provide a highly uniform ion flux and the source also efficiently dissipates heat generated by secondary electron emissions.

More specifically, the plasma doping system 100 includes a plasma chamber 102 that contains a process gas supplied by an external gas source 104. The process gas typically contains a dopant species that is diluted in a dilution gas. The external gas source 104, which is coupled to the plasma chamber 102 through a proportional valve 106. The external gas source 104 supplies the process gas to the chamber 102. A second external gas source 104′ is coupled to the plasma chamber 102 through a second proportional valve 106′. The second external gas source 104′ supplies a dilution gas to the process chamber 102. In various embodiments, the dilution gas can be a noble gas, such as helium or xenon, which provides electrons to the plasma that reduce the electronegativity of the plasma. Reducing the electronegativity of the plasma reduces positive charging on the surface of the substrate as described herein.

In some embodiments, a gas baffle is used to disperse the process and dilution gasses into the plasma source 101. A pressure sensor 108 measures the pressure inside the chamber 102. An exhaust port 110 in the chamber 102 is coupled to a vacuum pump 112 that evacuates the chamber 102. An exhaust valve 114 controls the exhaust conductance through the exhaust port 110.

A process controller 116 has an input that is electrically connected to the pressure sensor 108 and outputs that are electrically connected to the proportional valves 106, 106′, and to the exhaust valve 114. The process controller 116 generates electrical signals for the proportional valves 106, 106′ and the exhaust valve 114 that maintain the desired pressure in the plasma chamber 102 by controlling the exhaust conductance, the process gas flow rate, and the dilution gas flow rate in a feedback loop that is responsive to the pressure sensor 108.

The chamber 102 has a chamber top 118 including a first section 120 formed of a dielectric material that extends in a generally horizontal direction. A second section 122 of the chamber top 118 is formed of a dielectric material that extends a height from the first section 120 in a generally vertical direction. The first and second sections 120, 122 are sometimes referred to herein generally as the dielectric window. It should be understood that there are numerous variations of the chamber top 118. For example, the first section 120 can be formed of a dielectric material that extends in a generally curved direction so that the first and second sections 120, 122 are not orthogonal as described in U.S. patent application Ser. No. 10/905,172, which is incorporated herein by reference. In other embodiment, the chamber top 118 includes only a planer surface.

The shape and dimensions of the first and the second sections 120, 122 can be selected to achieve a certain performance. For example, one skilled in the art will understand that the dimensions of the first and the second sections 120, 122 of the chamber top 118 can be chosen to improve the plasma uniformity. In one embodiment, a ratio of the height of the second section 122 in the vertical direction to the length across the second section 122 in the horizontal direction is adjusted to achieve more uniform plasmas. For example, in one particular embodiment, the ratio of the height of the second section 122 in the vertical direction to the length across the second section 122 in the horizontal direction is in the range of 1.5 to 5.5.

The dielectric materials in the first and second sections 120, 122 provide a medium for transferring the RF power from the RF antenna to the plasma inside the chamber 102. In one embodiment, the dielectric material used to form the first and second sections 120, 122 is a high purity ceramic material that is chemically resistant to the process gases and that has good thermal properties. For example, in some embodiments, the dielectric material is 99.6% Al₂O₃ or AlN. In other embodiments, the dielectric material is Yittria and YAG.

A lid 124 of the chamber top 118 is formed of a conductive material that extends a length across the second section 122 in the horizontal direction. In many embodiments, the conductivity of the material used to form the lid 124 is high enough to dissipate the heat load and to minimize charging effects that results from secondary electron emission. Typically, the conductive material used to form the lid 124 is chemically resistant to the process gases. In some embodiments, the conductive material is aluminum or silicon.

The lid 124 can be coupled to the second section 122 with a halogen resistant O-ring made of fluoro-carbon polymer, such as an O-ring formed of Chemrz and/or Kalrex materials. The lid 124 is typically mounted to the second section 122 in a manner that minimizes compression on the second section 122, but that provides enough compression to seal the lid 124 to the second section. In some operating modes, the lid 124 is RF and DC grounded as shown in FIG. 1. In addition, in some embodiments, the lid 124 comprises a cooling system that regulates the temperature of the lid 124 and the surrounding area in order to dissipate the heat load generated during processing. The cooling system can be a fluid cooling system that includes cooling passages in the lid 124 which circulate a liquid coolant from a coolant source.

In some embodiments, the chamber 102 includes a liner 125 that is positioned to prevent or greatly reduce metal contamination by providing line-of-site shielding of the inside of the plasma chamber 102 from metal sputtered by ions in the plasma striking the inside metal walls of the plasma chamber 102. Such liners are described in U.S. patent application Ser. No. 11,623,739, filed Jan. 16, 2007, entitled “Plasma Source with Liner for Reducing Metal Contamination,” which is assigned to the present assignee. The entire specification of U.S. patent application Ser. No. 11/623,739 is incorporated herein by reference. In some embodiments, the plasma chamber liner 125 includes a temperature controller. In one particular embodiment, the temperature controller maintains the temperature of the liner 125 at a relatively low temperature that is sufficient for absorption of a film layer that generates neutrals during film desorption according to the present invention.

A RF antenna is positioned proximate to at least one of the first section 120 and the second section 122 of the chamber top 118. The plasma source 101 in FIG. 1 illustrates two separate RF antennas that are electrically isolated from one another. However, in other embodiments, the two separate RF antennas are electrically connected. In the embodiment shown in FIG. 1, a planar coil RF antenna 126 (sometimes called a planar antenna or a horizontal antenna) having a plurality of turns is positioned adjacent to the first section 120 of the chamber top 118. In addition, a helical coil RF antenna 128 (sometimes called a helical antenna or a vertical antenna) having a plurality of turns surrounds the second section 122 of the chamber top 118.

In some embodiments, at least one of the planar coil RF antenna 126 and the helical coil RF antenna 128 is terminated with a capacitor 129 that reduces the effective antenna coil voltage. The term “effective antenna coil voltage” is defined herein to mean the voltage drop across the RF antennas 126, 128. In other words, the effective coil voltage is the voltage “seen by the ions,” or equivalently, the voltage experienced by the ions in the plasma.

Also, in some embodiments, at least one of the planar coil RF antenna 126 and the helical coil RF antenna 128 includes a dielectric layer 134 that has a relatively low dielectric constant compared to the dielectric constant of the Al₂O₃ dielectric window material. The relatively low dielectric constant dielectric layer 134 effectively forms a capacitive voltage divider that also reduces the effective antenna coil voltage. In addition, in some embodiments, at least one of the planar coil RF antenna 126 and the helical coil RF antenna 128 includes a Faraday shield 136 that also reduces the effective antenna coil voltage.

A RF source 130, such as a RF power supply, is electrically connected to at least one of the planar coil RF antenna 126 and helical coil RF antenna 128. In many embodiments, the RF power source 130 is coupled to the RF antennas 126, 128 with an impedance matching network 132 that matches the output impedance of the RF source 130 to the impedance of the RF antennas 126, 128 in order to maximize the power transferred from the RF source 130 to the RF antennas 126, 128. Dashed lines from the output of the impedance matching network 132 to the planar coil RF antenna 126 and to the helical coil RF antenna 128 are shown to indicate that electrical connections can be made from the output of the impedance matching network 132 to either or both of the planar coil RF antenna 126 and the helical coil RF antenna 128.

In some embodiments, at least one of the planar coil RF antenna 126 and the helical coil RF antenna 128 is formed such that it can be liquid cooled. Cooling at least one of the planar coil RF antenna 126 and the helical coil RF antenna 128 will reduce temperature gradients caused by the RF power propagating in the RF antennas 126, 128. The helical coil RF antenna 128 can include a shunt 129 that can reduce the number of turns in the coil.

In some embodiments, the plasma source 101 includes a plasma igniter 138. Numerous types of plasma igniters can be used with the plasma source 101. In one embodiment, the plasma igniter 138 includes a reservoir 140 of strike gas, which is a highly-ionizable gas, such as argon (Ar), which assists in igniting the plasma. The reservoir 140 is coupled to the plasma chamber 102 with a high conductance gas connection. A burst valve 142 isolates the reservoir 140 from the process chamber 102. In another embodiment, a strike gas source is plumbed directly to the burst valve 142 using a low conductance gas connection. In some embodiments, a portion of the reservoir 140 is separated by a limited conductance orifice or metering valve that provides a steady flow rate of strike gas after the initial high-flow-rate burst.

A platen 144 is positioned in the process chamber 102 a height below the top section 118 of the plasma source 101. The platen 144 holds a target, which is referred to herein as the substrate 146, for plasma doping. In the embodiment shown in FIG. 1, the platen 144 is parallel to the plasma source 101. However, the platen 144 can also be tilted with respect to the plasma source 101. In some embodiments, the platen 144 is mechanically coupled to a movable stage that translates, scans, or oscillates the substrate 146 in at least one direction. In one embodiment, the movable stage is a dither generator or an oscillator that dithers or oscillates the substrate 146. The translation, dithering, and/or oscillation motions can reduce or eliminate shadowing effects and can improve the uniformity and conformality of the ion beam flux impacting the surface of the substrate 146.

The substrate 146 is electrically connected to the platen 144. An output of a bias voltage power supply 148 is electrically connected to the platen 144. The bias voltage power supply 148 generates a bias voltage waveform that biases the platen 144 and the substrate 146 so that dopant ions in the plasma are extracted from the plasma and impact the substrate 146. In various embodiments, the bias voltage power supply 148 can be a DC power supply, a pulsed power supply, or a RF power supply.

A shield ring 154 is positioned around the substrate 146. An output of a shield ring power supply 156 is electrically connected to the shield ring 154. In various embodiments, the shield ring power supply 156 biases the shield ring in a continuous mode or in a mode that is synchronized with the bias voltage waveform. In some methods according to the present invention, the shield ring power supply 156 biases the shield ring 154 with a negative voltage that is more negative than the voltage applied to the platen 144 and to the substrate 146 by the bias voltage waveform. The negative voltage on the shield ring 154 establishes an electric field that induces electrons to the surface of the substrate 146. The induced electrons reduce the positive charge accumulation on the surface of the substrate 146, thereby reducing the probability of an electrical discharge.

An output of the process controller 116 is electrically connected to a control input of the bias voltage power supply 148. The process controller 116 generates a control signal at the output that instructs the bias voltage power supply 148 to generate a bias voltage waveform that has a low probability of forming electrical discharges during plasma doping. The process controller 116 can include a memory that stores predetermine values for parameters used by the process controller 116 to generate a bias voltage waveform that has a low probability of forming electrical discharges under various conditions. The process controller 116 can also use an algorithm to determine various plasma doping parameters including the bias voltage waveform according to the present invention.

The plasma doping system 100 includes various sensors that measure data related to conditions favorable for forming an electrical discharge. In many embodiments, these sensors perform real time in-situ measurements of the conditions favorable for forming an electrical discharge. There are numerous types of sensors that can be used to measure these parameters.

One type of sensor that can be used to measure conditions favorable for forming an electrical discharge is the pressure sensor 108 that measures the pressure inside the chamber 102. The pressure sensor 108 can be used to determine the onset and/or the termination of outgassing from the photoresist layer or other materials on the substrate being ion implanted. An increase in pressure caused by outgassing of photoresist material or other materials present on the substrate can increase the probability of an electrical discharge.

Another type of sensor that can be used to measure conditions favorable for forming an electrical discharge is a Faraday dosimeter 170. The plasma doping system 100 includes a Faraday dosimeter 170 positioned on or proximate to the platen 144. An output of the Faraday dosimeter 170 is electrically connected to a sensor input of the process controller 116. The Faraday dosimeter 170 measures the dose of the ions being implanted in the surface of the substrate and generates a signal related to the measured dose of ions to the process controller 116. In some embodiments, the process controller 116 determines the dose per pulse.

In some embodiments, the plasma doping system 100 includes an optical emission spectrometer 172 that is positioned proximate to a window in the plasma chamber 102 so that it detects optical emission from the plasma. An output of the optical emission spectrometer 172 is electrically connected to a sensor input of the process controller 116. The optical emission spectrometer 172 generates signals indicating various optical emissions in the plasma. The optical emission spectrometer can determine changes in the plasma that result from the outgassing of photoresist material or other materials on the substrate 146. Also the optical emission spectrometer 172 can detect the onset of electrical discharges.

In some embodiments, the plasma doping system 100 includes a residual gas analyzer 174 that samples gas present in the process chamber 102. An output of the residual gas analyzer 174 is electrically connected to a sensor input of the process controller 116. The residual gas analyzer 174 is a type of mass spectrometer that measures trace gases in a low pressure environment. The residual gas analyzer 174 can detect the presence of outgassing of photoresist material or other materials present on the substrate 146.

Also, in some embodiments, the plasma doping system 100 includes a fault detector 176 that detects the electrical discharges in the plasma chamber 102. An output of the fault detector 176 is electrically connected to a sensor input of the process controller 116. The fault detector 176 sends a signal to the process controller 116 when an electrical discharge or micro-discharge current is detected. In various other embodiments, the plasma doping system 100 includes other sensors such as probes to measure the ion density in the plasma.

Some embodiments of the plasma doping system 100 include a means to generate neutrals for conformal doping or other applications. In some embodiments, the plasma doping system 100 includes a temperature controller that is used to control the temperature of the platen 144 and the temperature of the substrate 146. The temperature controller is designed to maintain the temperature of the substrate 146 at a relatively low temperature that is sufficient for absorption of a film layer that generates neutrals during film desorption according to the present invention. Also, in some embodiments, the plasma doping system 100 includes a separate neutral source that is positioned proximate to the substrate 146. Also, in some embodiments, the plasma doping system 100 includes a nozzle that injects a controlled amount of gas to absorb a film layer at predetermined times relative to bias voltage pulses generated by the bias voltage power supply 148 in order to enhance re-absorption of the film layer on the substrate 146. Also, in some embodiments, the plasma doping system 100 includes a radiation source that provides a burst or pulse of radiation that rapidly desorbs an absorbed film on the substrate 146. A plasma doping system with such features is described in U.S. patent application Ser. No. 11/774,587, filed Jul. 7, 2007 entitled “Conformal Doping Using High Neutral Density Plasma Implant.” The entire specification of U.S. patent application Ser. No. 11/774,587 is incorporated herein by reference.

One skilled in the art will appreciate that there are many different possible variations of the plasma doping system 100 that can be used with the features of the present invention. See for example, the descriptions of the plasma doping system in U.S. patent application Ser. No. 10/908,009, filed Apr. 25, 2005, entitled “Tilted Plasma Doping.” Also see the descriptions of the plasma doping system in U.S. patent application Ser. No. 11/163,303, filed Oct. 13, 2005, entitled “Conformal Doping Apparatus and Method.” Also see the descriptions of the plasma doping system in U.S. patent application Ser. No. 11/163,307, filed Oct. 13, 2005, entitled “Conformal Doping Apparatus and Method.” Also see the descriptions of the plasma doping system in U.S. patent application Ser. No. 11/566,418, filed Dec. 4, 2006, entitled “Plasma Doping with Electronically Controllable implant Angle.” Also see the descriptions of the plasma doping system in U.S. patent application Ser. No. 11/617,785, filed Dec. 29, 2006, entitled “Plasma Immersion Ion Source with Low Effective Antenna Voltage.” Also see the descriptions of the plasma doping system in U.S. patent application Ser. No. 11/623,739, filed Jan. 16, 2007, entitled “Liner for Plasma Doping Apparatus with Reduced Metal Contamination.” Also see the descriptions of the plasma doping system in U.S. patent application Ser. No. 11/676,069, filed Feb. 16, 2007, entitled “Multi-Step Plasma Doping with Improved Dose Control. Also see the descriptions of the plasma doping system in U.S. patent application Ser. No. 11/678,524, filed Feb. 23, 2007, entitled “Technique For Monitoring and Controlling A Plasma Process.” Also see the descriptions of the plasma doping system in U.S. patent application Ser. No. 11/687,822, filed Mar. 19, 2007 entitled “Method of Plasma Process With In-Situ Monitoring And Process Parameter Tuning. Also see the descriptions of the plasma doping system in U.S. patent application Ser. No. 11/771,190, filed Jun. 29, 2007, entitled “Plasma Doping with Enhanced Charge Neutralization.” In addition, see the descriptions of the plasma doping system in U.S. patent application Ser. No. 11/774,587, filed Jul. 7, 2007 entitled “Conformal Doping Using High Neutral Density Plasma Implant.” The entire specifications of these patent applications are incorporated herein by reference.

In operation, the RF source 130 generates an RF current that propagates in at least one of the RF antennas 126 and 128. That is, at least one of the planar coil RF antenna 126 and the helical coil RF antenna 128 is an active antenna. The term “active antenna” is herein defined as an antenna that is driven directly by a power supply. In some embodiments of the plasma doping apparatus of the present invention, the RF source 130 operates in a pulsed mode. However, the RF source can also operate in the continuous mode.

In some embodiments, one of the planar coil antenna 126 and the helical coil antenna 128 is a parasitic antenna. The term “parasitic antenna” is defined herein to mean an antenna that is in electromagnetic communication with an active antenna, but that is not directly connected to a power supply. In other words, a parasitic antenna is not directly excited by a power supply, but rather is excited by an active antenna positioned in electromagnetic communication with the parasitic antenna. In the embodiment shown in FIG. 1, the active antenna is one of the planar coil antenna 126 and the helical coil antenna 128 powered by the RF source 130. In some embodiments of the invention, one end of the parasitic antenna is electrically connected to ground potential in order to provide antenna tuning capabilities. In this embodiment, the parasitic antenna includes the coil adjuster 129 that is used to change the effective number of turns in the parasitic antenna coil. Numerous different types of coil adjusters, such as a metal short, can be used.

The RF currents in the RF antennas 126, 128 then induce RF currents into the chamber 102. The RF currents in the chamber 102 excite and ionize the process gas so as to generate a plasma in the chamber 102. The plasma chamber liner 125 shields metal sputtered by ions in the plasma from reaching the substrate 146.

The bias voltage power supply 148 biases the substrate 146 with a negative voltage that attracts ions in the plasma towards the substrate 146. During the negative voltage pulses, the electric field within the plasma sheath accelerates ions toward the substrate 146 which implants the ions into the surface of the substrate 146. A process of absorbing a film layer and then rapidly desorbing the film layer to generate neutrals that scatter ions for plasma doping can be used to enhance the conformality of the plasma doping as described in U.S. patent application Ser. No. 11/774,587, filed Jul. 7, 2007 entitled “Conformal Doping Using High Neutral Density Plasma Implant.”

In various embodiments of the present invention, the process controller 116 receives signals from the various sensors, such as the pressure sensor 108, Faraday dosimeter 170, optical emission spectrometer 172, residual gas analyzer 174, and the fault detector 176. The process controller 116 then generates a control signal for the proportional valve 106 that regulates the amount of process gas injected into the process chamber 102. In addition, the process controller 116 generates a control signal for the exhaust valve 114 that instructs the exhaust valve 114 to provide the desired exhaust conductance for maintaining the desired pressure in the plasma chamber 102.

In some embodiments, the process controller 116 also generates a control signal for the proportional valve 106′ that regulates the amount of dilution gas injected into the process chamber 102. Adding dilution gas changes the electronegativity of the plasma. Electronegativity is a well known measure of the ability of an atom to attract electrons. The type of bond formed by atoms is dependent on the difference in electronegativity between the atoms. Atoms with similar electronegativities will share an electron with each other and form a covalent bond. However, if the difference in electronegativity is too great, the electron will be permanently transferred to one atom and an ionic bond will form.

For example, in some embodiments, the process controller 116 generates a control signal for the proportional valve 106′ that regulates the amount of a noble dilution gas, such as helium or xenon, which is injected into the process chamber 102. The helium or xenon dilution gas provides electrons to the plasma, which reduces the electronegativity of the plasma. The electrons provided to the plasma reduce or eliminate positive charging on the surface of the substrate 146, thereby reducing the probability of generating an electrical discharge on the substrate 146.

In some embodiments, the process controller 116 generates a control signal for the shield ring power supply 156 that instructs the shield ring power supply 156 to generate a negative voltage on the shield ring 154 that is more negative than the bias voltage applied to the substrate 146 by the bias voltage power supply 148. In other embodiments, the shield ring power supply 156 continuously generates a negative voltage on the shield ring 154 that is more negative than the bias voltage applied to the substrate 146. In yet other embodiments, the shield ring power supply 156 generates a negative voltage on the shield ring 154 that is more negative than the bias voltage applied to the substrate 146 during off pulse times of the bias voltage waveform. In this embodiment, the output of the shield ring power supply 156 is synchronized to the bias voltage waveform and the negative voltage is applied only when a bias voltage pulse is not applied to the substrate 146.

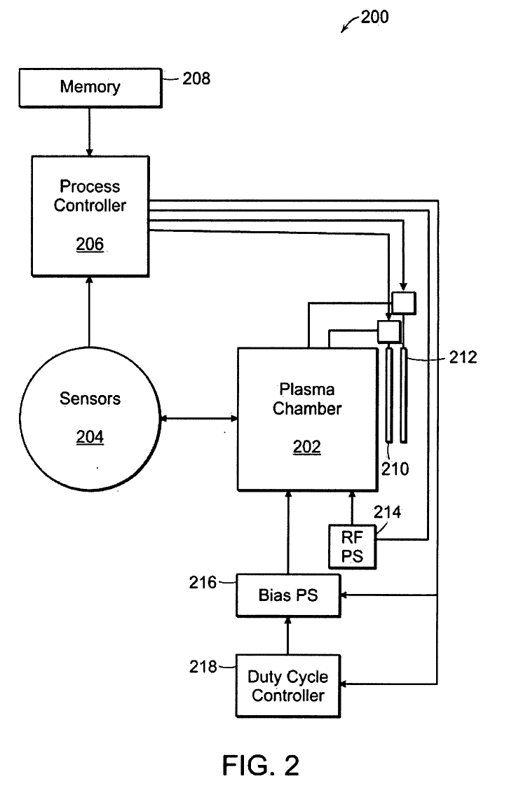

FIG. 2 illustrates a block diagram 200 of a plasma doping system with closed loop charge control according to the present invention. Referring to both FIGS. 1 and 2, the block diagram 200 shows a plasma chamber 202 for plasma doping. At least one sensor 204 is coupled to the process chamber 202. Any type of sensor that directly or indirectly measures a parameter related to forming an electrical discharge can be used. For example, the at least one sensor 204 can measure a parameter that is related to the positive charge accumulation on the substrate which increases the probability of forming an electrical discharge. In various embodiments, the at least one sensor 204 can includes a dosimeter, an ion density probe, a residual gas analyzer, and an optical spectrum analyzer. Numerous other types of sensors that measure parameters related to forming an electrical discharge are within the scope of the present invention.

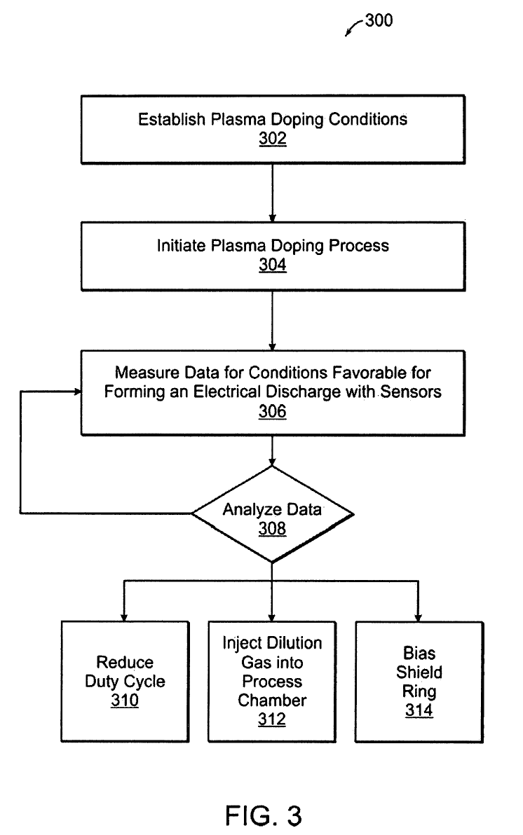

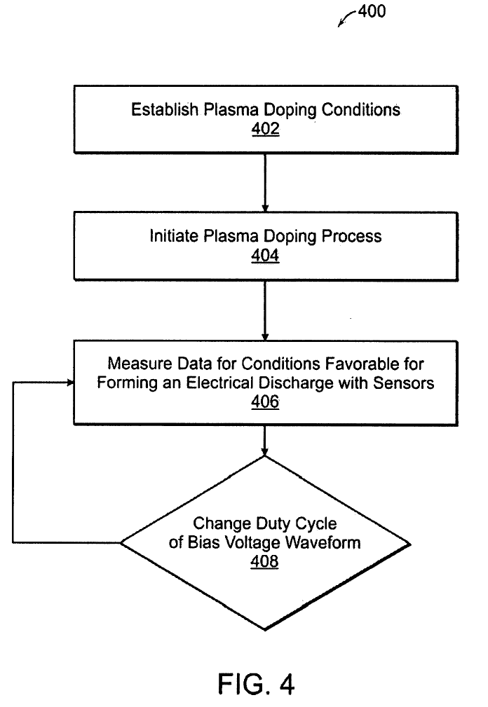

A process controller 206 receives initial parameters from a memory 208 and then generates initial control signals for a process gas source 210, a dilution gas source 212, the RF power supply 214 which generates the plasma, the bias voltage power supply 216 which biases the substrate, and the duty cycle controller 218, which controls the duty cycle of the bias voltage waveform. The process controller 206 also receives signals from the at least one sensor 204 and processes the signals to determine if plasma doping process parameters should be changed. In various embodiments, the process controller 206 compares data in these signals to stored data in the memory or uses the data in these signals in an algorithm to determine if process parameters should be changed. FIGS. 3 and 4 describe some methods of closed loop charge control with the plasma doping systems described in connection with FIGS. 1 and 2.

FIG. 3 illustrates a flow chart 300 of a method of closed loop charge control of a plasma doping system with various sensors that measure data related to conditions favorable for forming an electrical discharge. Referring to the plasma doping apparatus 100 of FIG. 1, in a first step 302, the plasma doping conditions are established with initial plasma doping parameters. The first step 302 includes performing any necessary pre-cleaning steps and also performing steps required to establish stable plasma doping conditions with conditions that are known to be unfavorable for forming an electrical discharge.

In a second step 304, the plasma doping process is initiated with the initial plasma doping process parameters. The target or substrate 146 is exposed to plasma doping ion flux and then biased with the bias voltage waveform determined in the first step 302 to have an amplitude and duty cycle that is known to be unfavorable for forming an electrical discharge.

In a third step 306, data related to conditions favorable for forming an electrical discharge is measured from various sensors. In various embodiments, data is measured from at least one sensor, such as the Faraday dosimeter 170, the optical emission spectrometer 172, the residual gas analyzer 174, and the fault detector 178 to determine if conditions are favorable for forming an electrical discharge. Data can also be measured from numerous other sensors for measuring these conditions.

In a fourth step 308, the data measured in the third step 306 is analyzed by the process controller 116 to determine if the current plasma doping process parameters should be changed to reduce the probability of forming an electrical discharge. In some embodiments, the data from the various sensors can be compared with stored data to determine if the current plasma doping process parameters should be changed. In other embodiments, the data from the various sensors is used in an algorithm to determine if process parameters should be changed to reduce the probability of forming an electrical discharge. If the analyzed data indicates that the probability of forming an electrical discharge is lower than a predetermined probability based upon the data measured in the third step 306, then the third step 306 is repeated and the various sensors continue to measure the data related to conditions favorable for forming an electrical discharge.

However, if the analyzed data indicates that the probability of forming an electrical discharge is higher than a predetermined probability based upon the data measured in the third step 306, then at least one of the fifth step 310, sixth step 312, and seventh step 314 is performed. In the fifth step 310, the duty cycle of the bias voltage waveform is reduced to reduce the probability of generating an electrical discharge as described herein. In the sixth step, a dilution gas is injected into the process chamber 102 to reduce the electronegativity of the plasma as described herein. In the seventh step 314, the shield ring 154 is biased with a negative voltage that is more negative than the voltage applied to the platen 144 and the substrate 146 in order to establish an electric potential that induces electrons to the surface of the substrate 146.

Once steps are taken to reduce the probability of forming an electrical discharge, the third step 206 is repeated and the various sensors continue to monitor the data related to conditions favorable for forming an electrical discharge. The four step 308 is then repeated and the fifth step 310, sixth step 312, and seventh step 314 is performed if necessary. This method is repeated during the plasma doping.

FIG. 4 illustrates a flow chart 400 of a method of closed loop charge control of a plasma doping system that adjusts the duty cycle of the bias voltage waveform so that conditions favorable for forming an electrical discharge are not established. Referring to the plasma doping apparatus 100 of FIG. 1, in a first step 402, the plasma doping conditions are established with initial plasma doping parameters. The first step 402 includes performing any necessary pre-cleaning steps and also performing steps required to establish stable plasma doping conditions with conditions that are known to be unfavorable for forming an electrical discharge.

In a second step 404, the plasma doping process is initiated with the initial plasma doping process parameters. The target or substrate 146 is exposed to plasma doping ion flux and then biased with the bias voltage waveform determined in the first step to have an amplitude and duty cycle that is known to be unfavorable for forming an electrical discharge.

In a third step 406, data related to conditions favorable for forming an electrical discharge is measured from various sensors. In various embodiments, data is measured from at least one sensor, such as the Faraday dosimeter 170, optical emission spectrometer 172, the residual gas analyzer 174, and the fault detector 178 to determine if conditions are favorable for forming an electrical discharge. Data can also be measured from numerous other sensors for measuring data related to these conditions.

In a fourth step 408, the data measured in the third step 406 is analyzed by the process controller 116 to determine if the duty cycle of the bias voltage waveform should be changed to reduce the probability of forming an electrical discharge. In some embodiments, the data from the various sensors can be compared with stored data to determine if the current duty cycle of the bias voltage waveform should be changed. In other embodiments, the data from the various sensors is used in an algorithm to determine if the duty cycle of the bias voltage waveform should be changed in order to reduce the probability of forming an electrical discharge.

If the analyzed data indicates that the probability of forming an electrical discharge is lower than a predetermined probability based upon the data measured in the third step 406, then the duty cycle is maintained at its current value or is increased. The third step 406 is then repeated and the various sensors continue to measure the data related to conditions favorable for forming an electrical discharge. However, if the analyzed data indicates that the probability of forming an electrical discharge is higher than a predetermined probability based upon the data measured in the third step 406, then the duty cycle of the bias voltage waveform is reduced, thereby reducing the probability of generating an electrical discharge.

### EQUIVALENTS

While the present teachings are described in conjunction with various embodiments and examples, it is not intended that the present teachings be limited to such embodiments. On the contrary, the present teachings encompass various alternatives, modifications and equivalents, as will be appreciated by those of skill in the art, may be made therein without departing from the spirit and scope of the invention.

What is claimed is:

1. A method of plasma doping comprising:
a. generating a plasma proximate to a platen supporting a substrate in a plasma chamber, the plasma comprising dopant ions;
b. biasing the platen with a bias voltage waveform having a negative potential that attracts ions in the plasma to the substrate for plasma doping;
c. monitoring at least one sensor measuring data related to charging conditions favorable for forming an electrical discharge; and
d. modifying at least one plasma process parameter in response to the measured data, thereby reducing a probability of forming an electrical discharge.

2. The method of claim 1 wherein the monitoring the at least one sensor comprises measuring a dose of ions implanted on the surface of the substrate.

3. The method of claim 1 wherein the monitoring the at least one sensor comprises measuring an ion density of the plasma.

4. The method of claim 1 wherein the monitoring the at least one sensor comprises measuring optical emissions from the plasma.

5. The method of claim 1 wherein the monitoring the at least one sensor comprises measuring residual gas in the process chamber.

6. The method of claim 1 wherein the monitoring the at least one sensor comprises measuring micro-discharge currents proximate to the substrate.

7. The method of claim 1 wherein the data related to charging conditions favorable for forming the electrical discharge comprises a measurement of charge accumulation on the substrate.

8. The method of claim 1 wherein the modifying the at least one plasma process parameter in response to the measured data comprises changing a duty cycle of the bias voltage waveform.

9. The method of claim 1 wherein the modifying the at least one plasma process parameter in response to the measured data comprises injecting a dilution gas into the plasma chamber, thereby reducing the electronegativity of the plasma.

10. The method of claim 1 further comprising generating an electric field proximate to the substrate that induces electrons proximate to the substrate, thereby reducing positive charge accumulation on the substrate.

11. The method of claim 10 wherein the modifying the at least one plasma process parameter in response to the measured data comprises modifying the electric field proximate to the substrate.

12. A method of plasma doping comprising:
a. generating a plasma in a plasma chamber proximate to a platen supporting a substrate, the plasma comprising dopant ions;
b. biasing the platen with a bias voltage waveform having a negative potential that attracts ions in the plasma to the substrate for plasma doping, the duty cycle of the bias voltage waveform being chosen to reduce the probability of forming an electrical discharge;
c. monitoring at least one sensor measuring data related to charging conditions favorable for forming an electrical discharge; and
d. adjusting the duty cycle of the bias voltage waveform in response to the measured data.

13. The method of claim 12 wherein the monitoring the at least one sensor comprises measuring a dose of ions implanted on the surface of the substrate.

14. The method of claim 12 wherein the monitoring the at least one sensor comprises measuring an ion density of the plasma.

15. The method of claim 12 wherein the monitoring the at least one sensor comprises measuring optical emission from the plasma.

16. The method of claim 12 wherein the monitoring the at least one sensor comprises measuring residual gas in the process chamber.

17. The method of claim 12 wherein the monitoring the at least one sensor comprises measuring micro-discharge current proximate to the substrate.

18. The method of claim 12 further comprising injecting a dilution gas into the plasma chamber, thereby reducing the electronegativity of the plasma.

19. The method of claim 12 further comprising modifying at least one plasma process parameter in response to the measured data.

20. The method of claim 12 further comprising generating an electric field proximate to the substrate that induces electrons proximate to the substrate, thereby reducing positive charge accumulation on the substrate.

21. A plasma doping apparatus comprising:
a. a chamber for containing a process gas;
b. a plasma source that generates a plasma from the process gas;
c. a platen that supports a substrate proximate to the plasma source for plasma doping;
d. a bias voltage power supply having an output that is electrically connected to the platen, the bias voltage power supply generating a bias voltage waveform with a negative potential that attracts ions in the plasma to the substrate for plasma doping;
e. at least one sensor that measures data related to charging conditions favorable for forming an electrical discharge; and
f. a process controller having an input electrically connected to an output of the at least one sensor and an output that is electrically connected to a control input of a bias voltage power supply, the process controller generating a signal that changes a duty cycle of the bias voltage waveform in response to the output of the at least one sensor.

22. The plasma doping apparatus of claim 21 further comprising a shield ring that is electrically connected to a power supply, the power supply generating an electric field proximate to the substrate that induces electrons proximate to the substrate, thereby reducing positive charge accumulation on the substrate.

23. The plasma doping apparatus of claim 21 wherein the at least one sensor comprises an optical emission spectrometer.

24. The plasma doping apparatus of claim 21 wherein the at least one sensor comprises a residual gas analyzer.

25. The plasma doping apparatus of claim 21 wherein the at least one sensor comprises an electrical discharge sensor.
